(19) United States
(12) Patent Application Publication
(10) Pub. No.: US 2011/0290310 A1
(43) Pub. Date: Dec. 1, 2011

(54) SOLAR CELL AND SOLAR CELL MANUFACTURING METHOD

(76) Inventors: Teruhiko KURAMACHI, Kanagawa (JP); Makoto Kikuchi, Kanagawa (JP); Takeshi Hama, Kanagawa (JP); Atsushi Tanaka, Kanagawa (JP); Youichi Hosoya, Kanagawa (JP)

(21) Appl. No.: 13/116,404

(22) Filed: May 26, 2011

(30) Foreign Application Priority Data
May 27, 2010 (JP) 2010-121571

(51) Int. Cl. H01L 31/06; H01L 31/18; B82Y 99/00

(52) U.S. Cl. 136/255; 438/87; 977/774; 977/948; 257/E31.037

(57) ABSTRACT

A solar cell capable of restricting carrier loss and yields higher energy conversion efficiency than was conventionally possible and a method of producing a solar cell enabling formation of a light absorbing layer containing quantum dots through a low-temperature process using a coating or printing method requiring no vacuum equipment or complicated apparatuses. The solar cell includes a light absorbing layer containing quantum dots in a matrix layer, and the light absorbing layer is connected to an N-type semiconductor layer on one side and to a P-type semiconductor layer on the other side. In the light absorbing layer, the quantum dots are made of nanocrystalline semiconductor and arranged 3-dimensionally uniformly enough and spaced regularly so that a plurality of wave functions lie on one another between adjacent quantum dots to form intermediate bands. The matrix layer is formed of amorphous IGZO.

### BACKGROUND OF THE INVENTION

The present invention relates to a solar cell comprising a light absorbing layer containing quantum dots in a matrix layer formed of amorphous IGZO and a method of manufacturing such solar cell and particularly to a solar cell that achieves a higher conversion efficiency by reducing the carrier loss and a method of manufacturing such solar cell.

Today, intensive researches are being conducted in solar cells. Among the solar cells, a PN-junction solar cell formed by connecting a P-type semiconductor and an N-type semiconductor and a PIN-junction solar cell formed by connecting a P-type semiconductor, an I-type semiconductor, and an N-type semiconductor absorb sunlight having a greater energy than the bandgap (Eg) between a conduction band and a valence band of a component semiconductor, and electrons are excited from the valence band to the conduction band to create positive holes in the valence band, thereby generating electromotive force in the solar cell.

The PN-junction solar cell and the PIN-junction solar cell each have a single bandgap and are called single-junction solar cells.

The PN-junction solar cell and the PIN-junction solar cell do not absorb but pass light having energy smaller than the bandgap. On the other hand, energy greater than the bandgap is absorbed, and out of the absorbed energy, an amount by which the absorbed energy is greater than the bandgap is consumed as thermal energy as phonons. Therefore, single-junction solar cells with a single bandgap such as PN-junction solar cells and PIN-junction solar cells have a problem of low energy conversion efficiency.

To lessen this problem, there have been developed multi-junction solar cells wherein a plurality of PN junctions and PIN junctions having different bandgaps are layered to form a structure that absorbs light in order of magnitude of energy in order to absorb light in a broad range of wavelength, reduce energy loss to heat energy, and thus improve energy conversion efficiency.

However, because such multi-junction solar cells have a plurality of PN junctions and PIN junctions electrically serially connected, the output current is a minimum current of the currents generated by the individual junctions. Therefore, a bias arises in the sunlight spectral distribution, and when the output of one PN junction or PIN junction decreases, the output of a junction that is not affected by the bias in the sunlight spectral distribution also decreases, thereby greatly reducing the output of the whole solar cell.

To make improvements in such problem, there have been proposed a quantum-dot solar cell having a multi-layer quantum well structure wherein semiconductor layers having different bandgaps are repeatedly layered with a size (thickness) sufficient to obtain quantum confinement effects in order to cause wave functions to lie on one another between quantum dots and thus form an intermediate band so as to absorb light in a broad range of wavelength, reduce energy loss to heat energy, and thus improve energy conversion efficiency (see JP 2007-535806 A, JP 2008-543029 A, and JP 2009-527108 A, and PHYSICAL REVIEW LETTERS, 78, 5014 (1997) and APPLIED PHYSICS LETTERS, 93, 263105 (2008)).

PHYSICAL REVIEW LETTERS, 78, 5014 (1997) proposes a quantum-dot solar cell having a superlattice structure in which semiconductors having two different bandgaps are formed into quantum dots and regularly arranged so as to cause bonding between quantum dots having 3-dimensional confinement effects, wherein a theoretical conversion efficiency can be made to exceed Shockley-Queisser limit and reach 60% by optimizing the combination of bandgaps of the component semiconductors.

APPLIED PHYSICS LETTERS, 93, 263105 (2008) describes setting the magnitude of quantum dots to dx=dy=dc≈4 nm in order to efficiently use quantum effects in a quantum-dot solar cell.

PHYSICAL REVIEW LETTERS, 78, 5014 (1997) describes, among others, a method of forming quantum dots through heteroepitaxial growth in a matrix semiconductor by a self-assembly method using an MBE apparatus or an MOCVD apparatus and a structure having quantum dots arranged in a matrix semiconductor.

However, the above method, whereby quantum dots are formed using the difference in lattice constant between quantum dot material and matrix material, cannot achieve simultaneously obtaining a quantum dot size and quantum dot arrays that produce ideal quantum confinement effects. Thus, such quantum dot size and quantum dot arrays that produce ideal quantum confinement effects are incompatible and hence a high energy conversion efficiency cannot be obtained.

Further, the above method requires relatively expensive devices and a specific crystal substrate to use crystal lattice arrays on the base substrate, making it difficult to secure a larger area and increasing the costs of the substrate.

To overcome the above problems, JP 2007-535806 A describes a method whereby stoichiometric layers and dielectric layers having a high semiconductor composition ratio are alternately layered and heated to crystallize and precipitate a amorphous dielectric material as a semiconductor rich in the matrix.

JP 2007-535806 A specifically describes forming a photoelectric conversion film in which crystalline quantum dots of an Si alloy are 3-dimensionally evenly distributed in a matrix material made of SiO₂, Si₃N₄, or SiC.

Solar cells using quantum dots and nanoparticles are also proposed in other literature than PHYSICAL REVIEW LETTERS, 78, 5014 (1997), APPLIED PHYSICS LETTERS, 93, 263105 (2008), and JP 2007-535806 A.

JP 2008-543029 A describes a method of achieving effective photoelectric conversion of sunlight using a solar cell having a lateral structure for dispersing wavelengths in a plane direction to achieve absorption and a vertical structure for vertically dispersing wavelengths to achieve absorption.

In JP 2008-543029 A, the lateral structure and the vertical structure are both composed of a condenser, a chromatic dispersion element, and a spectroscope and, therefore, complicated.

Solar cells having a vertical structure are so-called multi-junction solar cells and use quantum dots in some of the layers to control the Eg (bandgap) and lattice adjustment in order in order to obtain preferable junctions.

According to JP 2008-543029 A, the material of solar cells of both the lateral structure and the vertical structure comprises at least one of a multiple exciton generating solar cell and a multiple energy level (intermediate band) solar cell in association with the self-assembly production technology. The multiple exciton generating solar cell and the multiple energy level (intermediate band) solar cell use, for example, quantum dots made of silicon/germanium alloy (Si:Ge).

JP 2009-527108 A relates to manufacturing of a tandem type solar cell and describes a solar cell using nanoparticles at least in the IR region and comprising an Eg-controlled composite film. The above composite film using nanoparticles has a composite film structure composed of a matrix material made of a hall conductive polymer or an electron conductive polymer compounded with complementary nanoparticles.

### SUMMARY OF THE INVENTION

According to the description in JP 2007-535806 B, because of a high energy barrier offered by SiO₂ and Si₃N₄, energy bonding of quantum dots greatly varies with the distance between quantum dots, and therefore the electric charge distribution is liable to be uneven, causing loss due to distribution bias. Further, because of an excessively great bandgap difference between quantum dots and matrix energy, the electrons resulting from photoelectric conversion by quantum dots cannot be efficiently extracted.

With SiC, which has a smaller bandgap than SiO₂, Si₃N₄, carrier loss sharply increases when SiC is amorphized, and a high energy conversion efficiency cannot be obtained because of this loss.

Further, according to the description in JP 2007-535806 B, because an amorphous film of which the composition density distribution was changed is heated to a high temperature to precipitate quantum dots, there is a restriction that the materials forming the matrix and the quantum dots be of the same element. For example, when an Si alloy is used to form quantum dots, the matrix is an Si-based dielectric film or an Si-based semiconductor, and therefore the materials of the matrix material and the quantum dots cannot be selected as desired.

The solar cell described in JP 2007-535806 B requires a heat-resistant substrate to undergo a high-temperature process carried out at 700° C. to 1000° C. for 15 minutes or more and relatively expensive vacuum equipment, incurring high manufacturing costs.

To solve the problem of increased manufacturing costs due to relatively expensive vacuum equipment required, there has been proposed a method whereby a nanocrystalline semiconductor is previously formed from a liquid phase or the like and thereafter dispersed and thus incorporated into a matrix formed by a precursor such as a liquid silicon precursor, a photoconductive low-molecular semiconductor, or a photoconductive polymer semiconductor and deforming the nanocrystalline semiconductor, to form a light absorbing layer containing quantum dots through a solution process such as coating and printing methods that do not require vacuum equipment or complicated devices. However, because the matrix is formed using an organic material such as a liquid silicon precursor and a polymer or low-molecular photoconductive material, carrier loss is extremely great and a high energy conversion efficiency cannot be obtained.

On the other hand, according to the solar cell described in JP 2008-543029 A, the complexity of the layer structure, a multi-junction structure, causes a great loss particularly at junction interfaces. Therefore, a high energy conversion efficiency cannot be obtained.

Further, according to the description in JP 2009-527108 A, when the matrix is formed using an organic material such as a polymer or low-molecular photoconductive material, carrier loss is extremely great and a high energy conversion efficiency cannot be obtained.

A first object of the invention is to solve the problems associated with the above prior art and provide a solar cell capable of restricting carrier loss and yielding a higher energy conversion efficiency than was conventionally possible.

A second object of the invention is to provide a method of producing a solar cell allowing formation of a light absorbing layer containing quantum dots through a process carried out at a relatively low temperature.

A third object of the invention is to provide a method of producing a solar cell allowing formation of a light absorbing layer containing quantum dots through a solution step such as a coating or printing method without requiring vacuum equipment and complicated apparatuses.

To achieve the above objective, a first aspect of the present invention provides a solar cell comprising: an N-type semiconductor layer on one side of a light absorbing layer containing quantum dots in a matrix layer and a P-type semiconductor layer on the other side of the light absorbing layer, wherein the quantum dots are made of nanocrystalline semiconductor, the quantum dots being arranged 3-dimensionally uniformly enough and spaced regularly so that a plurality of wave functions lie on one another between adjacent quantum dots to form intermediate bands, and wherein the matrix layer is formed of amorphous IGZO.

Preferably, ε_{FA}>ε_{FB} holds, where ε_{FA} is a magnitude of energy from a conduction band to a Fermi level of the matrix layer, and ε_{FB} is a magnitude of energy from a conduction band to a Fermi level of the N-type semiconductor layer.

Preferably, the matrix layer has a bandgap of 3.2 eV to 3.8 eV.

Preferably, the amorphous IGZO has a composition expressed as In₂₋ₓGaₓO₃ (ZnO)ₘ, where 0.5<x<1.8 and 0.5≦m≦3.

Preferably, the quantum dots have a bandgap of 0.4 eV to 1.2 eV in a bulk state.

Preferably, the quantum dots are formed of Si, Si alloy, Ge, SiGe, InN, InAs, InSb, PbS, PbSe, or PbTe. In this case, Preferably, the Si alloy is FeSi₂, Mg₂Si, or CrSi₂. Preferably, the quantum dots have a mean diameter of 2 nm to 12 nm.

Also, a second aspect of the present invention provides a method of manufacturing a solar cell comprising an N-type semiconductor layer on one side of a light absorbing layer containing quantum dots in a matrix layer formed of amorphous IGZO and a P-type semiconductor layer on the other side of the light absorbing layer, the P-type semiconductor layer having a first electrode layer on a side opposite from the light absorbing layer, the N-type semiconductor layer having a second electrode layer on a side opposite from the light absorbing layer, wherein a step of forming the light absorbing layer comprises: a step of applying or printing a mixture of a first IGZO precursor in a state of liquid and a particle dispersed solution in which particles forming the quantum dots are dispersed in a solvent onto the N-type semiconductor layer or the P-type semiconductor layer and a heat treatment step to vaporize the solvent contained in the mixture.

Preferably, a step of forming the N-type semiconductor layer comprises: a step of applying or printing a second IGZO precursor in a state of liquid containing a solvent onto the light absorbing layer or the second electrode layer, and a heating step to vaporize the solvent contained in the second IGZO precursor.

Preferably, a step of forming the P-type semiconductor layer comprises: a step of applying or printing a precursor solution or a crystalline nanoparticle dispersed solution onto the light absorbing layer or the first electrode layer, and a step of vaporizing the solvent in the precursor solution or the solvent in the crystalline nanoparticle dispersed solution.

Preferably, the precursor solution contains a CuAlO₂ precursor. Preferably, the crystalline nanoparticle dispersed solution contains a CuGaS₂ particle dispersion.

Preferably, a passivation step for preventing occurrence of defects at interfaces between the quantum dots and the matrix layer and in the matrix layer after the light absorbing layer is formed.

Preferably, the passivation step comprises either a step of immersing the light absorbing layer in an ammonium sulfide solution or a cyanide solution or a step of heating the light absorbing layer in the presence of hydrogen gas, hydrogen fluoride gas, hydrogen bromide gas, or hydrogen phosphide gas.

The solar cell of the invention restricts carrier loss and yields a high energy conversion efficiency.

The method of producing a solar cell according to the present invention allows formation of the light absorbing layer containing quantum dots through a process accomplished at a relatively low temperature, for example 500° C., and even through a solution step such as a coating method or printing method without requiring vacuum equipment and complicated apparatuses. Thus, manufacturing costs can be reduced.

### BRIEF DESCRIPTION OF DRAWINGS

FIG. 1 is a schematic cross section illustrating a configuration of a solar cell according to an embodiment of the invention.

FIG. 2 is a schematic perspective illustrating a light absorbing layer of a solar cell according to an embodiment of the invention.

FIG. 3A is a schematic view illustrating an energy band structure of a light absorbing layer of a solar cell according to an embodiment of the invention; FIG. 3B is a schematic view for explaining light absorption in a light absorption layer of a solar cell according to an embodiment of the invention.

FIG. 4 is a schematic view illustrating an energy band structure of a solar cell according to an embodiment of the invention.

FIG. 5A is a schematic view illustrating an example of an energy band structure of a light absorption layer of a solar cell of the invention; FIG. 5B is a schematic view illustrating another example of an energy band structure of a light absorption layer of a solar cell of the invention.

FIG. 6A is a schematic view for explaining operations of a solar cell according to an embodiment of the invention; FIG. 6B is a schematic view for explaining an example of a cause leading to a reduced efficiency of a solar cell.

FIG. 7 is a schematic cross section illustrating another configuration of a solar cell according to an embodiment of the invention.

### DETAILED DESCRIPTION OF THE INVENTION

The solar cell and solar cell production method of the invention will be described below based on preferred embodiments illustrated in the attached drawings.

The present invention was made based on the following findings obtained by the present inventors.

Carrier loss due to amorphization of a matrix material is currently thought to be caused by the fact that crystals formed by covalent bond as exemplified by Si and SiC acquire a localized electronic state when the crystals enter a disorderly crystalline state caused by amorphization. It is inferred therefrom that amorphization causes a rapid increase in carrier loss, which in turn makes it impossible to obtain a high energy conversion efficiency. Thus, we thought that use of a material having a carrier conduction track spatially expanding without creating a localized state of electric charge improves conversion efficiency even in disorderly crystalline state caused by amorphization and searched for a material having such properties. As a result, we found that amorphous IGZO, an oxide semiconductor now starting to attract much attention in the field of TFT, is a material having a carrier conduction track spatially expanding without creating a localized state of electric charge even in disorderly crystalline state caused by amorphization and having properties not tending to make a defect level in the bandgap, and thought of using this material in a quantum dot solar cell to improve conversion efficiency.

Further, there is a need for thin-film solar cells such as a quantum dot solar cell to have a PIN junction structure where a greater part of the light absorption layer is positioned in a space-charge region (depletion layer, where an internal electric field exits), so that the carriers excited by sunlight can be immediately extracted through the internal electric field, skipping the step of transferring the carriers to the PN boundary by diffusion.

However, amorphous IGZO, typically having N-type semiconductor properties, does not allow PIN junction structure to be formed. Therefore, the present invention was made by finding a structure enabling extraction of excited electrons or positive holes immediately as photogenerated current.

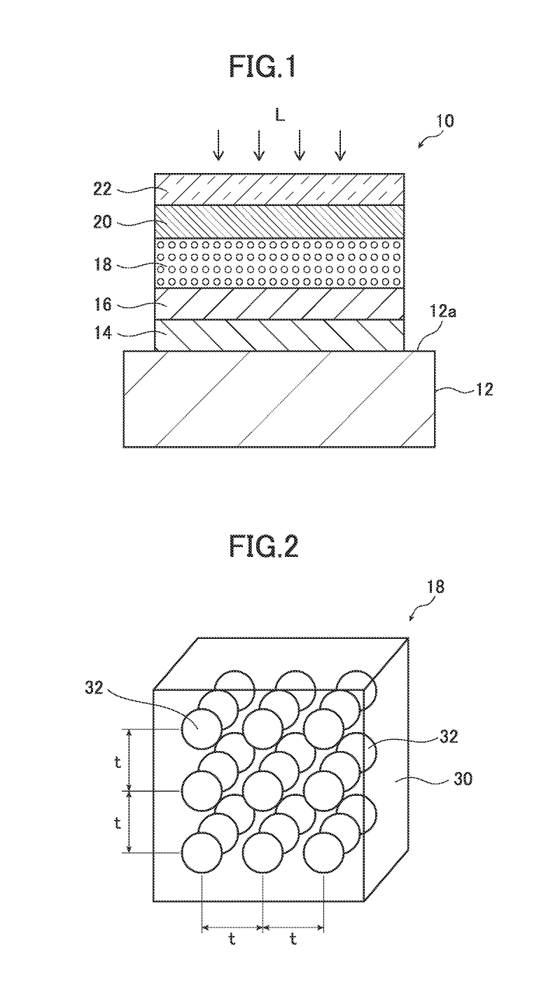

A solar cell 10 according to this embodiment illustrated in FIG. 1 is a substrate type comprising a substrate 12, an electrode layer 14, a P type semiconductor layer 16, a photoelectric conversion layer 18, an N-type semiconductor layer 20, and a transparent electrode layer 22.

The solar cell 10 has a layered structure formed on a surface 12a of the substrate 12. The layered structure is the electrode layer 14/the P-type semiconductor layer 16/the photoelectric conversion layer 18/the N-type semiconductor layer 20/the transparent electrode layer 22. In other words, the solar cell 10 comprises the N-type semiconductor layer 20 on one side of the light absorbing layer 18 and the P-type semiconductor layer 16 on the other side. The P-type semiconductor layer 16 is provided with the electrode layer 14 (first electrode layer) on the opposite side from the light absorbing layer 18. The N-type semiconductor layer 20 is provided with the transparent electrode layer 22 (second electrode layer) on the opposite side from the light absorbing layer 18.

The substrate 12 is made of a material having a relatively high heat resistance. The substrate 12 may be formed of, for example, a glass substrate such as a soda-lime glass substrate, a heat resistant glass substrate, a quartz glass substrate, a stainless steel substrate, a metallic multi-layer substrate having a layer structure composed of stainless steel sheets and those of other metals, an aluminum substrate, or an aluminum substrate provided with an oxide film having an improved surface insulation obtained by applying oxidation treatment to the surface, which may be achieved by, for example, anodization.

The electrode layer 14 is provided on the surface 12a of the substrate 12 to extract current obtained by the photoelectric conversion layer 18 along with the transparent electrode layer 22. The electrode layer 14 may be made of, for example, Mo, Cu, Cu/Cr/Mo, Cu/Cr/Ti, Cu/Cr/Cu, or Ni/Cr/Au.

When the electrode layer 14 is in contact with an N-type semiconductor layer, the electrode layer 14 is made of, for example, Nb-doped Mo, Ti/Au or the like.

The P-type semiconductor layer 16 is provided on the electrode layer 14 and in contact with the photoelectric conversion layer 18. The P-type semiconductor layer 16 is formed of, for example, a material having a bandgap equal to or greater than that of the amorphous IGZO forming a matrix layer 30 of the photoelectric conversion layer 18 described later. Materials having a bandgap equal to or greater than that of IGZO or amorphous IGZO and which may be used herein include, for example an alloy expressed as ABO₂. In the alloy expressed as ABO₂, A is, for example, Cu or Ag and B is, for example, Al, Ga, In, Sb, or Bi. Further, one may use the alloy expressed as ABO₂, a solid-solution based material thereof, a Delafossite type microcrystallite, or an alloy composed of 2 or 3 kinds of these materials. The P-type semiconductor layer 16 may also be formed of, for example, CuAlS₂, CuGaS, or B doped SiC.

The N-type semiconductor layer 20 has the same composition as the matrix layer 30 of the photoelectric conversion layer 18 described later. The N-type semiconductor layer 20 is formed, for example, of amorphous IGZO expressed as In₂₋ₓGaₓO₃ (ZnO)ₘ (0.5<x<1.8, 0.5≦m≦3).

The transparent electrode layer 22 extracts current obtained by the photoelectric conversion layer 18 along with the electrode layer 14 and is provided over the whole surface of the N-type semiconductor layer 20. The transparent electrode layer 22 may be provided on a part of the N-type semiconductor layer 20. Sunlight L is admitted into the solar cell 10 from the transparent electrode layer 22 side.

The transparent electrode layer 22 is formed of a material exhibiting an N-type conductivity. The transparent electrode layer 22 may be made of IGZO; Ga₂O₃, SnO₂ based (ATO, FTC), ZnO based (AZO, GZO), In₂O₃ based (ITO), or Zn (O, S) CdO having a bandgap equal to or greater than that of amorphous IGZO, or an alloy composed of 2 or 3 kinds of these materials. Further, the transparent electrode layer 22 may be made, for example, of MgIn₂O₄, GaInO₃, or CdSb₃O₆.

According to this embodiment, the P-type semiconductor layer 16 and the N-type semiconductor layer 20 have a thickness of, for example, 50 nm to 300 nm, preferably 100 nm.

According to this embodiment, the P-type semiconductor layer 16 and the N-type semiconductor layer 20 have an electron mobility of, for example, 0.01 cm²/Vsec to 100 cm²/Vsec, preferably 1 cm²/Vsec to 100 cm²/Vsec.

As illustrated in FIG. 2, the photoelectric conversion layer 18 comprises a plurality of quantum dots 32 in the matrix layer 30. In the photoelectric conversion layer 18, a layer formed of the quantum dots 32 and the matrix layer 30 form a pair in constituting a PNN layer structure having 20 to 50 periods.

In the photoelectric conversion layer 18, the quantum dots 32 are distributed 3-dimensionally uniformly enough and spaced regularly so that a plurality of wave functions lie on one another between adjacent quantum dots 32 to form intermediate bands.

Specifically, the quantum dots 32 are arranged at intervals t of 10 nm or less, preferably 2 nm to 6 nm.

The quantum dots 32 have a mean particle diameter of, for example, 2 nm to 12 nm, preferably 2 nm to 6 nm. Variation in particle diameter of the quantum dots 32 is preferably within plus or minus 20%.

The quantum dots 32 are formed of a nanocrystal semiconductor having a bandgap of, for example, 0.4 eV to 1.2 eV in, for example, a bulk state. Specifically, the quantum dots 32 are formed of Si, Si alloy, Ge, SiGe, InN, InAs, InSb, PbS, PbSe, PbTe, or the like. The Si alloy is, for example, FeSi₂, Mg₂Si, or CrSi₂, or the like.

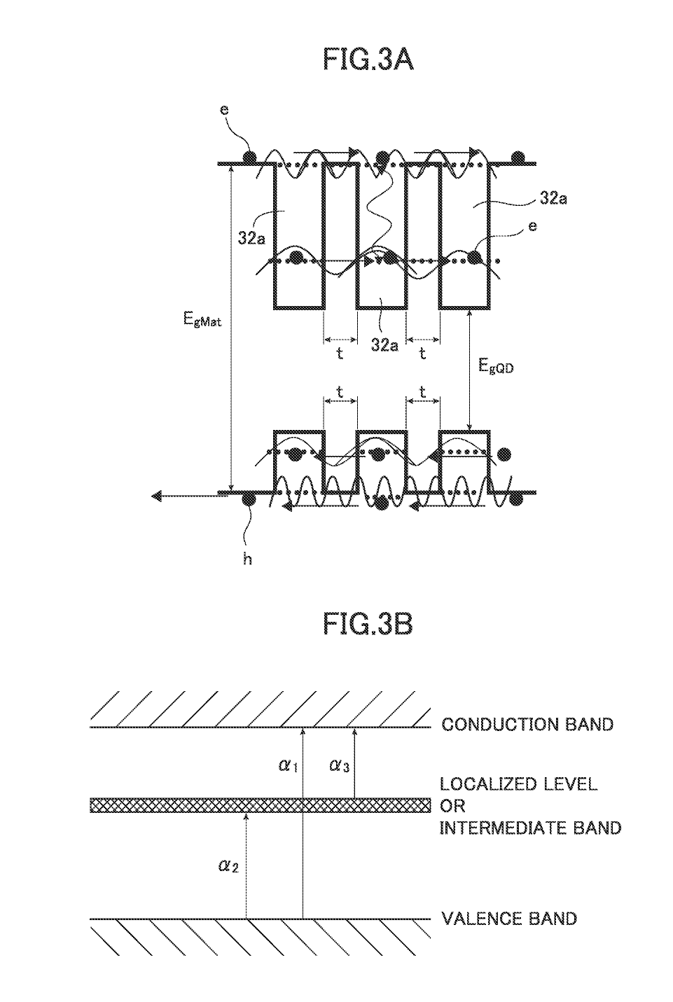

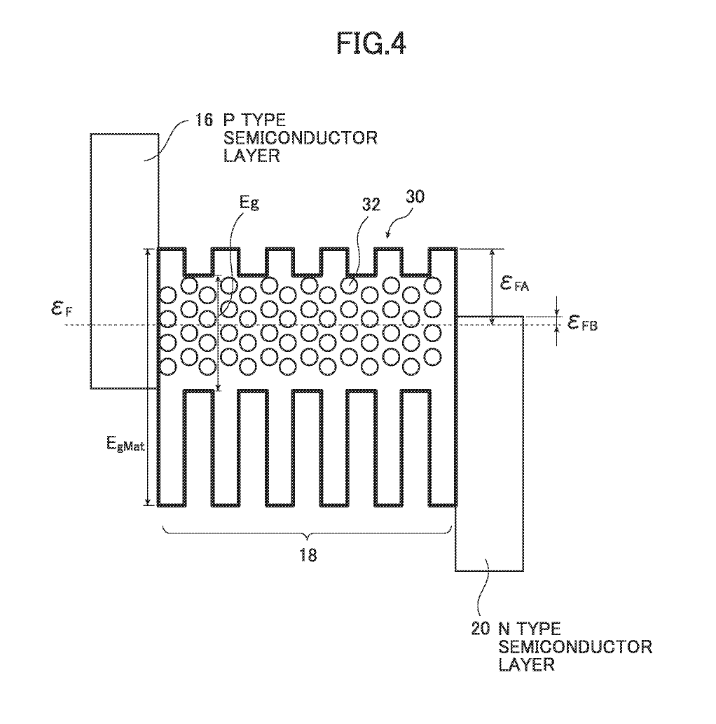

With the quantum dots 32 thus configured and arranged, the tunnel probability between the quantum wells 32a formed by the quantum dots 32 as illustrated in FIG. 3A increases, the fluctuation increases, the loss due to carrier transport is improved, and the speed of electron movement between the quantum dot wells 32a or quantum dots 32 is increased. In FIG. 3A, Egₘₐₜ indicates the bandgap of the matrix layer 30; Eg_{QD} indicates the bandgap of the quantum dots 32.

In the photoelectric conversion layer 18, the matrix layer 30 containing the quantum dots 32 is formed, for example, of amorphous IGZO expressed as In₂₋ₓGaₓO₃ (ZnO)ₘ (0.5<x<1.8, 0.5≦m≦3). The matrix layer 30 preferably has a thickness of, for example, 200 nm to 800 nm, preferably 400 nm.

The bandgap of the amorphous IGZO forming the matrix layer 30 can be controlled by controlling the composition of the amorphous IGZO. Specifically, we found that the bandgap can be set to 3.2≦Eg≦3.8 eV by changing the density of Ga in In₂₋ₓGaₓO₃ (ZnO)ₘ to 0.5<x<1.8 and setting m to 0.5≦m≦3.

When the bandgap (Egₘₐₜ) of the matrix layer 30 is 3.2≦Egₘₐₜ≦3.8 eV, the bandgap (Eg_{QD}) of the quantum dots 32 in a quantum dot mode is preferably 0.8≦Eg_{QD}≦1.5.

With the above configuration, the light absorbing layer 18 according to this embodiment comprises a localized level or an intermediate band as illustrated in FIG. 3B. Thus, the light absorbing layer 18 absorbs light αₗ having energy equal to or greater than the bandgap between valence band and conduction band, light α₂ having energy equal to or greater than the bandgap between valence band and localized level or intermediate band, and light α₃ having energy equal to or greater than the bandgap from valence band and localized level, thereby generating electromotive force in the light absorbing layer 18.

In the light absorbing layer 18, ε_{FA}>ε_{FB} preferably holds, where, as illustrated in FIG. 4, ε_{FA} is the magnitude of energy from the conduction band of the matrix layer 30 to the Fermi level ε_{F}, and ε_{FB} is the magnitude of energy from the conduction band of the N-type semiconductor layer 20 to the Fermi level ε_{F}. The solar cell 10 according to this embodiment preferably has an energy band structure where ε_{FA}>ε_{FB} holds.

We further studied the variation in energy position from conduction band to Fermi level in an amorphous IGZO film not containing quantum dots. We consequently found that depending on the film property of the amorphous IGZO film, the magnitude of the energy from the conduction band to the Fermi level ε_{F} can be varied in a range of 0.01 eV<ε_{F}<0.6 eV by changing the composition ratio Ga/(In+Ga) (at ratio) of the IGZO film or by changing the conditions for an ultimate vacuum immediately preceding the film formation during formation of the amorphous IGZO film. The magnitude of energy from the conductor to the Fermi level ε_{F} is estimated from the activation energy at room temperature RT.

We further found that with ε_{FA}>ε_{FB}, electric fields generated by the Fermi difference cause carrier transfer. We also found that with ε_{FA}−ε_{FB}>0.3 eV, the carrier transfer is improved.

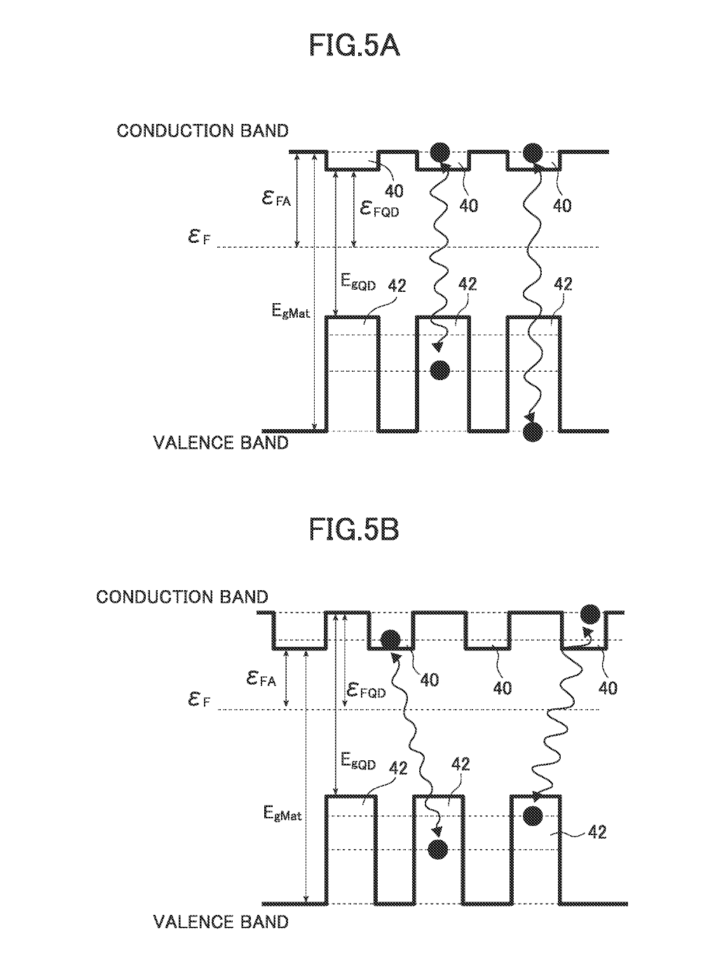

In the light absorbing layer 18 (matrix layer 30) of the solar cell 10, the position from the conduction band of the amorphous IGZO to the Fermi level ε_{F} is not located at the center between the valence band and the conduction band as illustrated in FIGS. 5A and SB. Therefore, the energy band structure is of type I and type II depending on the magnitude of the band gap (Eg_{QD}) of the quantum dots 32.

Now, let ε_{FQD} be the energy from the conduction band of the quantum dots 32 to the Fermi level ε_{F}, then when the relationship with the energy ε_{FA} from the conduction band to the Fermi level ε_{F} of the matrix layer 30 (amorphous IGZO) is ε_{FA}≧ε_{FQD}, the energy band structure is of type I illustrated in FIG. 5A. On the other hand, when ε_{FA}≦ε_{FQD}, the energy band structure is of type II illustrated in FIG. 5B.

In the case of the energy band structure of type I illustrated in FIG. 5A, quantum wells 40 formed in the conduction band and quantum wells 42 formed in the valence band coincide in position, so that similar characteristics are exhibited as in conventional quantum dot solar cells.

On the other hand, in the case of the energy band structure of type II illustrated in FIG. 5B, the quantum wells 40 formed in the conduction band and the quantum wells 42 formed in the valence band differ in position, so that the excitation is of indirect transition type. Therefore, although the proportion of excitation caused by light absorption decreases, the probability of the excited carriers falling into the quantum wells also decreases, which in turn also reduces the proportion of carrier recombination.

Because the loss in carrier transport in the matrix layer 30 is improved according to the invention, the energy conversion efficiency can be improved whether the energy band structure is of type I or of type II.

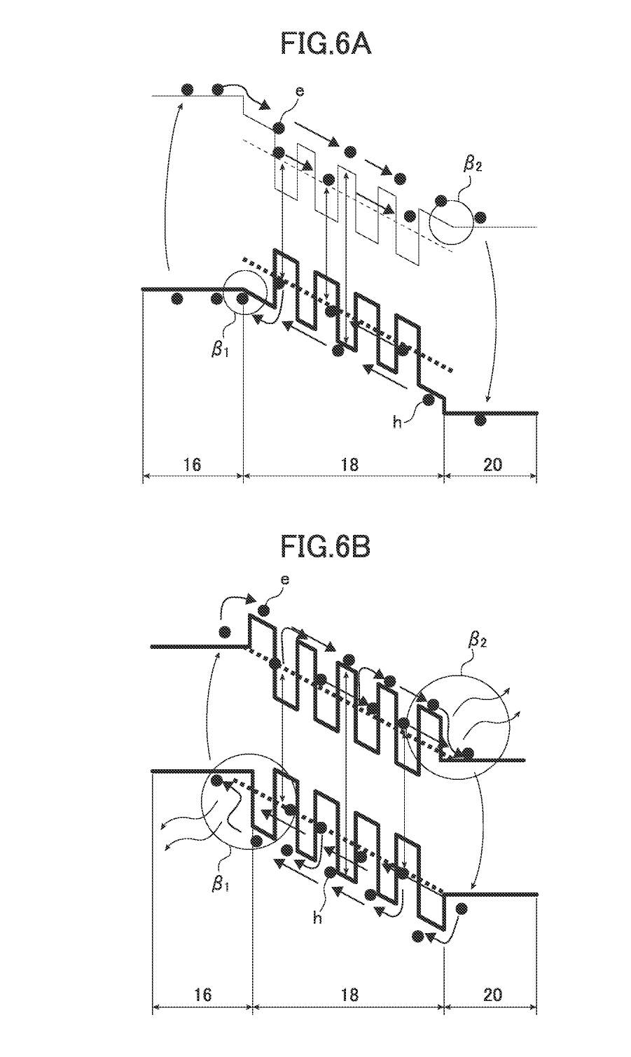

In the solar cell 10 according to this embodiment, when sunlight enters the light absorbing layer 18, electrons e are excited from the valence band to the conduction band by the above three kinds of light αₗto light α₃ in the light absorbing layer 18 (see FIG. 3B), and positive holes h are produced in the valence band to generate electromotive force in the solar cell 10. In this case, the quantum dots 32 are distributed 3-dimensionally uniformly enough and spaced regularly so that a plurality of wave functions lie on one another between adjacent quantum dots 32 to form intermediate bands, thus reducing the loss occurring during transfer of electrons e. Moreover, since the P-type semiconductor layer 16 is formed of a material having a bandgap equal to or greater than that of the amorphous IGZO forming the matrix layer 30 of the photoelectric conversion layer 18, the loss due to the bandgap difference is restricted as the positive holes h cross a boundary β₁ between the P-type semiconductor layer 16 and the photoelectric conversion layer 18 illustrated in FIG. 6A. Further, since the N-type semiconductor layer 20 is formed of the same material as the matrix layer 30 of the photoelectric conversion layer 18, the loss due to the bandgap difference is restricted as the electrons e cross a boundary β₂ between the photoelectric conversion layer 18 and the N-type semiconductor layer 20. Accordingly, the solar cell 10 is capable of a higher energy conversion efficiency than the prior art.

When the P-type semiconductor layer 16 is not formed of a material having a bandgap equal to or greater than that of the amorphous IGZO forming the matrix layer 30, the loss due to the bandgap difference occurs as the positive holes h cross the boundary β₁ between the P-type semiconductor layer 16 and the photoelectric conversion layer 18 illustrated in FIG. 6B. Further, also when the N-type semiconductor layer 20 is not formed of a material having a bandgap equal to or greater than that of the amorphous IGZO forming the matrix layer 30, the loss due to the bandgap difference occurs as the positive holes h cross the boundary β₂ between the photoelectric conversion layer 18 and the N-type semiconductor layer 20 illustrated in FIG. 6B. Thus, high energy conversion efficiency cannot be obtained. Therefore, the P-type semiconductor layer 16 and the N-type semiconductor layer 20 are preferably formed of a material having a bandgap equal to or greater than that of the amorphous IGZO forming the matrix layer 30.

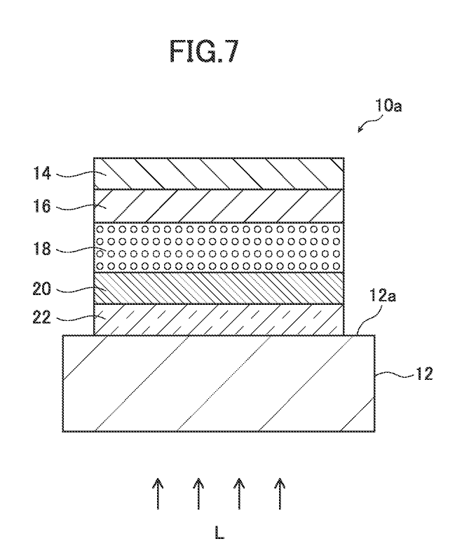

Note that the configuration of the solar cell is not specifically limited. The solar cell according to the invention may have a configuration called the superstrate type having a layer structure comprising the transparent electrode layer 22 provided on the surface 12a of the substrate 12 and placed thereon the N-type semiconductor layer 20, the light absorbing layer 18, the P-type semiconductor layer 16, and the electrode layer 14 as exemplified by a solar cell 10a illustrated in FIG. 7. Note that sunlight L enters the solar cell 10a illustrated in FIG. 7 from the substrate 12 side.

Next, the production method of the solar cell 10 according to this embodiment will be described.

A first method of producing the solar cell 10 will be first described. First, a glass substrate, for example, is provided as the substrate 12.

Next, using a sputter target made of Mo, a Mo electrode layer is formed on the substrate 12 as the electrode layer 14 by DC sputtering method or RF sputtering method.

Then, CuGaO₂ powder of which the composition has been previously determined using the XRD pattern is vapor-deposited by pulse laser vapor deposition at a film formation temperature RT (room temperature, about 25° C.) to form the P-type semiconductor layer 16.

Subsequently, cosputtering is effected on the P-type semiconductor layer 16 using a sputter target made of IGZO monocrystal (composition ratio (at ratio) In:Ga:Zn=1:1:1) and a sputter target made of SiGe crystal (composition ratio (at ratio) Si:Ge=8:2) at a film formation temperature RT (room temperature, about 25° C.) and under ultimate vacuum of 4.8×10⁻³ Pa under respective conditions to form the quantum dots 32 made of SiGe in the matrix 30 made of amorphous IGZO. Thus, the light absorbing layer 18 is formed.

Thereafter, sputtering is effected using only a sputter target made of IGZO monocrystal (composition ratio (at ratio) In:Ga:Zn=1:1:1) to form an amorphous IGZO film on the light absorbing layer 18 at a film formation temperature RT (room temperature, about 25° C.) and under ultimate vacuum of 3.8×10⁻⁶ Pa, whereupon the film is annealed at 180° C. in an oxygen atmosphere. Thus, the N-type semiconductor layer 20 is formed.

Next, using a sputter target made of Mo, a Mo electrode layer for extracting current is formed on a part of the N-type semiconductor layer 20 as the transparent electrode layer 22 by DC sputtering method or RF sputtering method. Thus, the solar cell 10 according to this embodiment can be produced.

We made findings about the amorphous IGZO forming the matrix layer 30 that the magnitude of energy from the conduction band to the Fermi level can be varied by changing the composition ratio Ga/(In+Ga) (at ratio) of the amorphous IGZO and by changing the back pressure conditions during formation of the amorphous IGZO film. In this case, the magnitude of energy from the conduction band to the Fermi level of the amorphous IGZO forming the matrix layer 30 is 0.017 eV under ultimate vacuum of 3.8×10⁻⁶ Pa and 0.337 eV under ultimate vacuum of 4.8×10⁻³ Pa.

According to this embodiment, a passivation step may be added before or after the oxygen annealing step carried out at 180° C. in order to prevent occurrence of defects in the interfaces between the quantum dots 32 and the matrix layer 30 and in the matrix layer 30. The passivation step may be carried out using a method whereby immersion is effected in a solution such as an ammonium sulfide solution or a cyanide solution and a method whereby heating is applied in a gas atmosphere of hydrogen gas, hydrogen fluoride gas, hydrogen bromide gas, hydrogen phosphide gas, or the like, among other methods. A method is selected from these according to the component material of the quantum dots 32. For Si-based quantum dots, for example, one may use a method whereby immersion is effected in a cyanide solution, followed by washing with acetone, ethanol, and ultrapure water.

Besides the first production method described above, the solar cell 10 according to this embodiment may be produced by other production methods as well. Next, a second method of producing the solar cell 10 according to this embodiment will be described. Since the procedure leading to a step of forming the P-type semiconductor layer 16 is the same as in the first production method, detailed descriptions thereof will not be made below.

Next, an IGZO precursor wherein SiGe nanoparticles are dispersed is applied or printed onto the P-type semiconductor layer 16 and heated at 200° C. to vaporize the solvent and form a coating film. This step of applying or printing the IGZO precursor onto the P-type semiconductor layer 16 followed by heating at 200° C. (heat treatment step) to vaporize the solvent is repeated. Then, upon sintering at 500° C., a step of oxygen annealing at 180° C. follows. Thus, the light absorbing layer 18 is formed.

Since the following procedure of producing the N-type semiconductor layer 20 and the transparent electrode layer 22 is the same as in the above first production method, detailed descriptions thereof will not be made below. Thus, the solar cell 10 according to this embodiment can be produced.

Also the second production method may include a passivation step before or after the oxygen annealing step carried out at 180° C. in order to prevent occurrence of defects at the interfaces between the quantum dots 32 and the matrix layer 30 and in the matrix layer 30. Since the passivation step is the same as in the passivation step in the first production method, detailed descriptions thereof will not be made below.

The method of applying or printing an IGZO precursor containing SiGe nanoparticles dispersed therein in the step of forming the light absorbing layer 18 may be carried out by, for example, a spray method, a roll coating method, a curtain method, a spin coating method, a screen printing method, an offset printing method, or an ink jet printing method.

The method of heating the above IGZO precursor to vaporize the solvent may be carried out by, for example, a method using a hot plate or an oven and, in addition to this heating method, a method using photoirradiation to promote decomposition/synthesis reaction of the organic solvent and the precursor.

Light sources for photoirradiation herein include excimer lasers, YAG lasers, argon lasers, visible light, ultraviolet ray, far ultraviolet ray, low-pressure or high-pressure mercury lamps, deuterium lamps, and rare gas discharge light.

Next, a third method of producing the solar cell 10 according to this embodiment will be described.

First, similarly to the above first production method, an No electrode layer is formed on the substrate 12 as the electrode layer 14, and a toluene solvent dispersed CuGaS₂ particle dispersion (crystalline nanoparticle dispersed solution) is applied or printed onto the substrate 12 as the electrode layer 14, followed by heating at 200° C. to vaporize the solvent and form a coating film, and this step is repeated.

Next, an IGZO precursor wherein SiGe nanoparticles are dispersed is applied or printed and heated at 200° C. to vaporize the solvent and form a coating film. This step of applying or printing the IGZO precursor followed by heating at 200° C., vaporizing the solvent and forming a coating film is repeated.

Subsequently, a second IGZO precursor is applied or printed, followed by heating at 200° C., vaporizing the solvent, and forming a coating film, and this step is repeated. Then, upon sintering at 500° C., a step of oxygen annealing at 180° C. follows. Thus, the P-type semiconductor layer 16, the photoelectric conversion layer 18, and the N-type semiconductor layer 20 are formed.

The transparent electrode layer 22 is formed in the same manner as in the first production method described above. Thus, the solar cell 10 according to this embodiment can be produced.

Next, a fourth method of producing the solar cell 10 according to this embodiment will be described.

First, a glass substrate is provided as the substrate 12. Then, a Cu/Cr/Cu electrode layer is formed on the surface 12a of the glass substrate 12 as the electrode layer 14 using, for example, a sputtering method.

Next, a CuAlO₂ precursor solution is applied or printed in an argon atmosphere or a nitrogen atmosphere, followed by heating at 400° C. to vaporize the solvent, and this step is repeated until the film thickness reaches about 0.5 nm. Subsequently, an IGZO precursor containing InN nanoparticles dispersed therein is applied or printed and heated at 200° C. to vaporize the solvent. Further, the second IGZO precursor is applied or printed and heated at 200° C. to vaporize the solvent. Then follows sintering at 500° C. Thereafter, oxygen annealing at 180° C. follows Thus, the P-type semiconductor layer 16, the photoelectric conversion layer 18, and the N-type semiconductor layer 20 are formed.

Next, using a sputter target made of Mo doped with Nb, an Nb-doped Mo electrode layer for extracting current is formed on a part of the N-type semiconductor layer 20 as the transparent electrode layer 22 by DC sputtering method or RF sputtering method. Thus, the solar cell 10 according to this embodiment can be produced.

The above steps of applying or printing toluene solution dispersed CuGaS₂ particle dispersion; applying or printing an IGZO precursor containing SiGe nanoparticles dispersed therein; and applying or printing the second IGZO precursor in the above third production method; and applying or printing a CuAlO₂ precursor solution; applying or printing an IGZO precursor containing InN particles dispersed therein; and applying or printing the second IGZO precursor in the above fourth production method may be all carried out using, for example, a spray method, a roll coating method, a curtain coating method, a spin coating method, a screen printing method, an offset printing method, or an ink jet printing method.

The method of applying or printing followed by heating to vaporize the solvent in the above third and fourth production methods may be carried out by, for example, a method using a hot plate or an oven and, in addition to this heating method, a method using photoirradiation to promote decomposition/synthesis reaction of the organic solvent and the precursor.

Light sources for photoirradiation herein include excimer lasers, YAG lasers, argon lasers, visible light, ultraviolet ray, far ultraviolet ray, low-pressure or high-pressure mercury lamps, deuterium lamps, and rare gas discharge light.

Further, a passivation step may be added before or after the oxygen annealing step carried out at 180° C. in order to prevent occurrence of defects at the interfaces between the quantum dots 32 and the matrix layer 30 and in the matrix layer 30. Since the passivation step is the same as in the passivation step in the first production method, detailed descriptions thereof will not be made below.

Next, a method of producing the toluene solution dispersed CuGaS₂ particle dispersion used in the third production method will be described. This CuGaS₂ particle dispersion may be obtained as follows.

First, 1 mmol (millimole) of acetylacetone copper and 1 mmol of acetylacetone gallium are dissolved in dichlorobenzene, oleic acid, or oleylamine to prepare a solution A. A simple sulfur is dissolved in dichlorobenzene, oleic acid, or oleylamine to prepare a solution B.

Then, with the solutions A and B kept at 110° C., the solution A is added to an Ar-bubbled solution B, whereupon the resulting solution is heated to 200° C. and left to react for 2 hours. After the reaction, an excess amount of ethanol is added, followed by centrifugation, whereupon the supernatant is removed before re-dispersion by toluene. This procedure is repeated several times to finally obtain toluene solution dispersed CuGaS₂.

Next, a method of producing a CuAlO₂ precursor of the CuAlO₂ precursor solution used in the fourth production method will be described. This CuAlO₂. precursor may be obtained as follows.

First, 15 mmol of copper acetate monohydrate is dissolved into 200 ml of ethanol solvent, and the resultant solution is mixed with 0.6 mol of methoxyethanol solvent, followed by addition of a 20-ml aluminum tri-sec-butoxide solution and agitation.

Then, the solution is refluxed for about 2 hours and subjected to about 2 hours of distillation to obtain a CuAlO₂ precursor having a metal ion concentration (Cu²⁺ and Al³⁺) of 0.5 mol/l. Where necessary, a dopant element, such as Be, Mg, and Ca replacing the Al site, may be dissolved into the above precursor solution in an amount depending on a desired concentration to adjust the Al/Cu ratio or increase the conductivity.

Next, a method of preparing the first IGZO precursor will be described. The first IGZO precursor may be obtained as follows. The first IGZO precursor has a composition ratio (at ratio) of, for example, Ga/(In+Ga)=¾.

First, 6.6 g of zinc acetate dihydrate is dissolved into 200 ml of ethanol solvent, and the solution is agitated at 90° C. for 1 hour. After the 100-ml ethanol solvent in this solution is vaporized, a 180-ml diethylethanolamin solvent is added, followed by addition of 1.37 g of indium triisopropoxide and 4.11 g of gallium triisopropoxide. Then, agitation at 60° C. is effected for 1 hour followed by 1 hour of agitation at 170° C. to vaporize a sum of 150 ml of the ethanol solvent or the diethylethanolamin solvent. Thus, the first IGZO precursor having a composition ratio (at ratio) of In:Ga:Zn=0.5:1.5:3 can be obtained.

Next, a method of preparing the second IGZO precursor will be described. The second IGZO precursor may be obtained as follows. The second IGZO precursor has a composition ratio (at ratio) of, for example, Ga/(In+Ga)=¼.

First, 2.2 g of zinc acetate dihydrate is dissolved into a 100-ml ethanol solvent, and the solution is agitated at 90° C. for 1 hour. After the 60-ml ethanol solvent in this solution is vaporized, a 180-ml diethylethanolamin solvent is added, followed by addition of 4.11 g of indium triisopropoxide and 1.37 g of gallium triisopropoxide. Then, agitation at 60° C. is effected for 1 hour followed by 1 hour of agitation at 170° C. to vaporize a sum of 120 ml of the ethanol solvent or the diethylethanolamin solvent. Thus, the second IGZO precursor having a composition ratio (at ratio) of In:Ga:Zn=1:1:1 can be obtained.

We made findings about the amorphous IGZO forming the matrix layer 30 that the magnitude of energy from the conduction band to the Fermi level can be varied by changing the composition ratio Ga/(In+Ga) (at ratio). Specifically, when Ga/(In+Ga)=¼, the energy is 0.08 eV; when Ga/(In+Ga)=¾, the energy is 0.591 eV.

Next, a method of preparing a SiGe nanoparticle dispersed solution will be described. A SiGe nanoparticle dispersed solution may be obtained as follows.

First, 236 mmol of TOAB (tetraoctylammonium bromide) is dissolved into a 330 ml-toluene solvent, followed by a 20-minute ultrasonic agitation. Thereto is added a solution containing a mixture of 55.6 mmol each of SiCl₄ and GeCl₄, followed by a 20-minute ultrasonic agitation.

Next, a 220-mmol THF (tetrahydrofuran) solution in which LiAlH₄ is dissolved is added, followed by a 30-minute ultrasonic agitation. Then, 50 mol of methanol solvent is added, followed by a 30-minute ultrasonic agitation. Subsequently, 2 mol of dodecen and 2 ml of methanol solvent in which H₂PtCl₆ is dissolved are added, followed by a 60-minute ultrasonic agitation. Thereafter, the solvent component in the solution is vaporized in a reduced-pressure atmosphere, and 100 ml of hexadecene is added. Thus, the SiGe nanoparticle dispersed solution may be obtained.

SiGe nanoparticles are selected so that the mean particle diameter is 2 nm to 10 nm and the variation in particle diameter is within plus or minus 1 nm, which depends on the SiGe composition.

Next, a method of preparing a SiGe nanoparticle dispersed IGZO precursor used in the above second and third production methods. A SiGe nanoparticle dispersed IGZO precursor may be obtained as follows.

First, a 800-ml solution of the above first IGZO precursor is prepared. The solvent component in the solution is vaporized in a reduced-pressure atmosphere until the solution is reduced to 400 ml. Then, a 100-ml SiGe nanoparticle dispersed solution is prepared and added to the above first vaporized IGZO precursor solution, followed by agitation to achieve uniform dispersion. Thus, the SiGe nanoparticle dispersed IGZO precursor may be obtained.

Next, a method of preparing an InN particle dispersed solution will be described.

An InN nanoparticle dispersed solution may be obtained as follows.

First, a 120-ml toluene solvent and a 20-ml trioctylamine solvent are mixed to prepare a mixed solution. Then, 16.6 mmol of InBr₃ and 49.8 mmol of NaN₃ are added thereto and dissolved by agitation at room temperature. Next, the temperature of this solution is raised to 150° C. at a rate of 5° C./h with agitation, then the solution is left to stand at 150° C. for 2 hours. Next, the temperature of the solution is raised to 200° C. at a rate of 5° C./h. Subsequently, the solution is left to stand at 200° C. for 4 hours, whereupon the temperature of the solution is raised to 260° C. at a rate of 2° C./h and then the solution is kept at that temperature for 1 hour before heating is terminated to allow the solution to naturally cool down to room temperature.

The solution, now cooled to room temperature, is ethanol-substituted, and substitution is thereafter repeated with a mixed solution containing glycerin and ethanol mixed at a ratio of 1:1 to remove salt and the like. Subsequently, the InN particles are selected so that the mean particle diameter is 2 nm to 10 nm and the variation in particle diameter is within plus or minus 1 nm. Thus, the InN particle dispersed solution may be obtained.

Next, a method of producing an InN particle dispersed IGZO precursor will be described. An InN particle dispersed IGZO precursor may be obtained as follows.

First, a 800-ml solution of the above first IGZO precursor is prepared. The solvent component in the solution is vaporized in a reduced-pressure atmosphere until the solution is reduced to 400 ml. Then, the above InN particle dispersed solution is prepared in an amount of 100 mml and added to the vaporized solution, followed by agitation to achieve uniform dispersion. Thus, the InN particle dispersed IGZO precursor may be obtained.

According to this embodiment, as described later, the solar cell 10 illustrated in FIG. 1 was produced and its efficiency was verified.

First, a glass substrate was used as the substrate 12 and No metal was used as a sputter target to form a No electrode layer on the glass substrate as the electrode layer 14 by DC sputtering method or RF sputtering method. Then, CuGaO₂ powder of which the composition has been determined using the XRD pattern was vapor-deposited by pulse-laser vapor deposition at a film formation temperature of about 25° C. to a thickness of about 200 nm and thus form the P-type semiconductor layer 16.

Next, an Si particle dispersed IGZO precursor was applied or printed onto the P-type semiconductor layer 16 using a spinner, followed by heating to 200° C. in an nitrogen atmosphere to vaporize the solvent and thus form a coating film. This procedure was repeated several times to form a coating film having a thickness of 400 nm. Then, annealing at 500° C. in an nitrogen atmosphere followed. Then followed immersion in a cyan solution, washing with acetone, ethanol, and ultrapure water, and oxygen annealing at 180° C. Thus, the light absorbing layer 18 was formed.

Thereafter, sputtering is effected using a sputter target made of IGZO monocrystal (composition ratio (at ratio) In:Ga:Zn=1:1:1) to form a 100 nm-thick amorphous IGZO film as the N-type semiconductor layer 20 on the light absorbing layer 18 at a film formation temperature of about 25° C. and under ultimate vacuum of 3.8×10⁻⁶ Pa. Then, the amorphous IGZO film was annealed at 180° C. in an oxygen atmosphere. Thus, the N-type semiconductor layer 20 was formed.

Next, using a sputter target made of Mo, a 200 nm-thick Mo electrode layer for extracting current was formed on a part of the N-type semiconductor layer 20 as the transparent electrode layer 22 by DC sputtering method or RF sputtering method.

Measurements were made to determine the conversion efficiency achieved by the solar cell thus obtained using a solar simulator under an AM (air mass) of 1.5 at room temperature and under atmospheric pressure. The solar cell measures 10 mm×10 mm. The measurements showed that the conversion efficiency η was 0.8%.

There is a report that a silicon quantum dot superlattice solar cell wherein silicon quantum dots are 3-dimensionally and regularly arranged in an amorphous SiC matrix has a conversion efficiency η of 0.05%. Therefore, the solar cell of the invention is capable of conversion efficiency that is sufficiently greater than is possible with conventional solar cells.

As described above, the solar cell of the invention yields a high energy conversion efficiency even when the matrix of the light absorbing layer is made of amorphous IGZO. The solar cell of the invention can be formed using a glass substrate and produced at a relatively low-temperature process at a process temperature of 500° C. or lower. This feature enables application of the large-area process using a glass substrate and selection of a variety of processes such as coating method and printing method already industrialized for FPDs, etc., thus enabling reduction of costs for producing the solar cell.

Now, a method of preparing an Si nanoparticle dispersed solution will be described. An Si nanoparticle dispersed solution may be obtained as follows.

First, 118 mmol of TOAB (tetraoctyl ammonium bromide) is dissolved into a 165-ml toluene solvent, followed by a 20-minute ultrasonic agitation. Then, a 55.6-mol SiCl₄ solution is added, followed by a 20-minute ultrasonic agitation.

Next, a 110-mmol THF (tetrahydrofuran) solution in which LiAlH₄ is dissolved is added, followed by a 30-minute ultrasonic agitation. Then, 25 ml of methanol is added, followed by a 30-minute ultrasonic agitation. Subsequently, 1 mol of dodecen and 1 ml of methanol in which H₂PtCl₆ is dissolved are added, followed by a 60-minute ultrasonic agitation. Thereafter, the solvent component in the solution is vaporized in a reduced-pressure atmosphere, followed by addition of hexadecene. Thus, an Si nanoparticle dispersed solution may be obtained.

Next, a method of producing a Si nanoparticle dispersed IGZO precursor will be described. A Si nanoparticle dispersed IGZO precursor may be obtained as follows.

First, an 800-ml solution of the above first IGZO precursor is prepared. The solvent component in the solution is vaporized in a reduced-pressure atmosphere until the solution is reduced to 400 ml. Then, the above Si nanoparticle dispersed solution is prepared in an amount of 100 mml and added to the vaporized solution, followed by agitation to achieve uniform dispersion. Selection of Si nanoparticles is made so that the mean particle diameter is 2 nm to 10 nm and the variation in particle diameter is within plus or minus 1 nm. Thus, an Si nanoparticle dispersed IGZO precursor may be obtained.

The present invention is basically as described above. While the solar cell of the invention and the solar cell production method have been described above in detail, the present invention is by no means limited to the above embodiments, and various improvements or design modifications may be made without departing from the scope and spirit of the present invention.

What is claimed is:

1. A solar cell comprising:
an N-type semiconductor layer on one side of a light absorbing layer containing quantum dots in a matrix layer and a P-type semiconductor layer on the other side of the light absorbing layer,
wherein the quantum dots are made of nanocrystalline semiconductor, the quantum dots being arranged 3-dimensionally uniformly enough and spaced regularly so that a plurality of wave functions lie on one another between adjacent quantum dots to form intermediate bands, and
wherein the matrix layer is formed of amorphous IGZO.

2. The solar cell according to claim 1, wherein ε_{FA}>ε_{FB} holds, where ε_{FA} is a magnitude of energy from a conduction band to a Fermi level of the matrix layer, and ε_{FB} is a magnitude of energy from a conduction band to a Fermi level of the N-type semiconductor layer.

3. The solar cell according to claim 1, wherein the matrix layer has a bandgap of 3.2 eV to 3.8 eV.

4. The solar cell according to claim 1, wherein the amorphous IGZO has a composition expressed as In₂₋ₓGaₓO₃ (ZnO)ₘ, where 0.5<x<1.8 and 0.5≦m≦3.

5. The solar cell according to claim 1, wherein the quantum dots have a bandgap of 0.4 eV to 1.2 eV in a bulk state.

6. The solar cell according to claim 5, wherein the quantum dots are formed of Si, Si alloy, Ge, SiGe, InN, InAs, InSb, PbS, PbSe, or PbTe.

7. The solar cell according to claim 6, wherein the Si alloy is FeSi₂, Mg₂Si, or CrSi₂.

8. The solar cell according to claim 1, wherein the quantum dots have a mean diameter of 2 nm to 12 nm.

9. The solar cell according to claim 1, wherein the quantum dots have a variation in particle diameter of plus or minus 20% or less.

10. A method of manufacturing a solar cell comprising an N-type semiconductor layer on one side of a light absorbing layer containing quantum dots in a matrix layer formed of amorphous IGZO and a P-type semiconductor layer on the other side of the light absorbing layer, the P-type semiconductor layer having a first electrode layer on a side opposite from the light absorbing layer, the N-type semiconductor layer having a second electrode layer on a side opposite from the light absorbing layer,
wherein a step of forming the light absorbing layer comprises:
a step of applying or printing a mixture of a first IGZO precursor in a state of liquid and a particle dispersed solution in which particles forming the quantum dots are dispersed in a solvent onto the N-type semiconductor layer or the P-type semiconductor layer and
a heat treatment step to vaporize the solvent contained in the mixture.

11. The method of manufacturing a solar cell according to claim 10, wherein a step of forming the N-type semiconductor layer comprises:
a step of applying or printing a second IGZO precursor in a state of liquid containing a solvent onto the light absorbing layer or the second electrode layer, and
a heating step to vaporize the solvent contained in the second IGZO precursor.

12. The method of manufacturing a solar cell according to claim 10, wherein a step of forming the P-type semiconductor layer comprises:
a step of applying or printing a precursor solution or a crystalline nanoparticle dispersed solution onto the light absorbing layer or the first electrode layer, and
a step of vaporizing the solvent in the precursor solution or the solvent in the crystalline nanoparticle dispersed solution.

13. The method of manufacturing a solar cell according to claim 12, wherein the precursor solution contains a CuAlO₂ precursor.

14. The method of manufacturing a solar cell according to claim 12, wherein the crystalline nanoparticle dispersed solution contains a CuGaS₂ particle dispersion.

15. The method of manufacturing a solar cell according to claim 10, comprising a passivation step for preventing occurrence of defects at interfaces between the quantum dots and the matrix layer and in the matrix layer after the light absorbing layer is formed.

16. The method of manufacturing a solar cell according to claim 15, wherein the passivation step comprises either a step of immersing the light absorbing layer in an ammonium sulfide solution or a cyanide solution or a step of heating the light absorbing layer in the presence of hydrogen gas, hydrogen fluoride gas, hydrogen bromide gas, or hydrogen phosphide gas.
